(19) United States
(12) Patent Application Publication
(10) Pub. No.: US 2021/0025933 A1
(43) Pub. Date: Jan. 28, 2021

(54) SEMICONDUCTOR APPARATUS

(71) Applicant: HUAIAN IMAGING DEVICE MANUFACTURER CORPORATION, HUAIAN (CN)

(72) Inventors: Tienchi KO, HUAIAN (CN); Fengmei SU, HUAIAN (CN)

(73) Assignee: HUAIAN IMAGING DEVICE MANUFACTURER CORPORATION, HUAIAN (CN)

(21) Appl. No.: 16/922,542

(22) Filed: Jul. 7, 2020

(30) Foreign Application Priority Data
Jul. 24, 2019 (CN) 201910671260.4

(51) Int. Cl. G01R 31/26; H01L 27/02; H01L 23/60; H02H 9/04

(52) U.S. Cl. CPC G01R 31/2623; H02H 9/04; H01L 23/60; H01L 27/0255

(57) ABSTRACT

A semiconductor apparatus includes: a device having a terminal; and a protection circuit configured to be connected to the terminal of the device, the protection circuit including at least two unidirectional conduction circuits connected in anti-parallel, the two unidirectional conduction circuits configured to have current directions opposite to each other in an on state, wherein the protection circuit is so configured that, at least one of the two unidirectional conduction circuits is turned on to release charges accumulated at the terminal when a voltage at the terminal of the device is out of a predetermined protection voltage range

### CROSS-REFERENCE TO RELATED APPLICATIONS

This application claims priority to Chinese Patent Application No. 201910671260.4, filed on Jul. 24, 2019, which is hereby incorporated by reference in its entirety.

### TECHNICAL FIELD

The present disclosure relates to the field of semiconductor technology, and more particularly, to a semiconductor apparatus.

### BACKGROUND

In a semiconductor manufacturing process, a plasma process such as plasma etching is often involved, and plasma damage is easily formed in a semiconductor apparatus, causing for example a gate capacitor breakdown of a field effect transistor, resulting in a decrease in yield.

In addition, in semiconductor technology, it is often necessary to test electrical characteristics and the like for the semiconductor apparatus. During the test, a relatively high test voltage or current possibly results in damage of the semiconductor apparatus.

### SUMMARY

According to an aspect of the present disclosure, a semiconductor apparatus is provided. The semiconductor apparatus includes: a device having a terminal; and a protection circuit configured to be connected to the terminal of the device, the protection circuit including at least two unidirectional conduction circuits connected in anti-parallel, the two unidirectional conduction circuits configured to have current directions opposite to each other in an on state, wherein the protection circuit is so configured that, when the voltage at the terminal of the device is out of a predetermined protection voltage range, at least one of the two unidirectional conduction circuits is turned on to release charges accumulated at the terminal.

Further features of the present disclosure and advantages thereof will become apparent from the following detailed description of exemplary embodiments with reference to the attached drawings.

### BRIEF DESCRIPTION OF THE DRAWINGS

The accompanying drawings, which constitute a part of the specification, illustrate embodiments of the present disclosure and, together with the description, serve to explain the principles of the present disclosure.

The present disclosure will be better understood according the following detailed description with reference of the accompanying drawings, wherein:

FIG. 1 shows a structural schematic diagram of a semiconductor apparatus.

FIG. 2 shows a structural schematic diagram of another semiconductor apparatus.

FIG. 3 shows a structural schematic diagram of a semiconductor apparatus according to an exemplary embodiment of the present disclosure.

FIG. 4 shows a test input signal according to an exemplary embodiment of the present disclosure.

FIG. 5 shows a CV characteristic curve of a gate capacitance of a field effect transistor according to an exemplary embodiment of the present disclosure.

Note that, in the embodiments described below, in some cases the same portions or portions having similar functions are denoted by the same reference numerals in different drawings, and description of such portions is not repeated. In some cases, similar reference numerals and letters are used to refer to similar items, and thus once an item is defined in one figure, it need not be further discussed for following figures.

In order to facilitate understanding, the position, the size, the range, or the like of each structure illustrated in the drawings and the like are not accurately represented in some cases. Thus, the disclosure is not necessarily limited to the position, size, range, or the like as disclosed in the drawings and the like.

### DETAILED DESCRIPTION

Various exemplary embodiments of the present disclosure will be described in details with reference to the accompanying drawings in the following. It should be noted that the relative arrangement of the components and steps, the numerical expressions, and numerical values set forth in these embodiments do not limit the scope of the present invention unless it is specifically stated otherwise.

The following description of at least one exemplary embodiment is merely illustrative in nature and is in no way intended to limit this disclosure, its application, or uses. That is to say, the structure and method discussed herein are illustrated by way of example to explain different embodiments according to the present disclosure. It should be understood by those skilled in the art that, these examples, while indicating the implementations of the present disclosure, are given by way of illustration only, but not in an exhaustive way. In addition, the drawings are not necessarily drawn to scale, and some features may be enlarged to show details of some specific components.

Techniques, methods and apparatus as known by one of ordinary skill in the relevant art may not be discussed in detail, but are intended to be regarded as a part of the specification where appropriate.

In all of the examples as illustrated and discussed herein, any specific values should be interpreted to be illustrative only and non-limiting. Thus, other examples of the exemplary embodiments could have different values.

In the semiconductor manufacturing process, a plasma process, such as plasma etching, is typically involved in order to form various structures of the semiconductor apparatus. However, in the plasma process, a conductor such as a metal line or polysilicon that has been formed can collect charges generated by plasma, and generate a voltage on an insulating layer such as a gate capacitance or a passivation layer in the semiconductor apparatus. When the voltage generated is too high, and the charges accumulated on the insulating layer cannot be released in time, plasma damage is easily generated in the insulating layer, and even the insulating layer is broken down, causing the yield of the semiconductor apparatus is decreased. In addition, after the manufacture of the semiconductor apparatus is finished, it is often necessary to further measure its electrical characteristic parameters and the like within a certain target test voltage range. During the test, potential safety hazards may also arise due to the relatively high applied test voltage, which correspondingly produce a relatively high voltage at the terminal of the device. In order to avoid the destruction of the semiconductor apparatus during the above-described manufacture and test, a protection circuit may be provided therein.

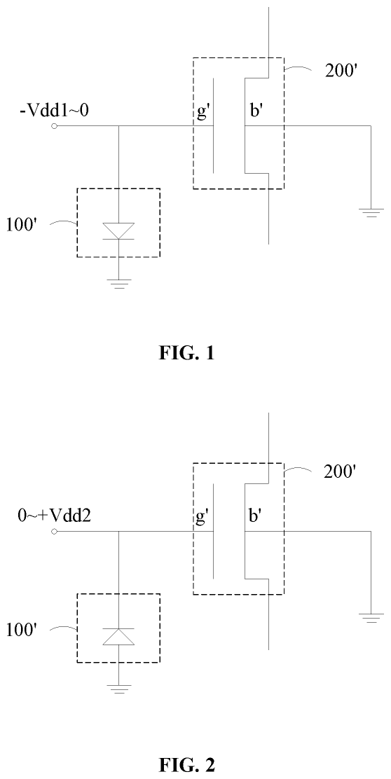

FIG. 1 shows a structural schematic diagram of a semiconductor apparatus. As shown in FIG. 1, the semiconductor apparatus can include a device 200′ and a protection circuit 100′ connected to a terminal of the device 200′. In the example shown in FIG. 1, the device 200′ is an N-type metal oxide semiconductor field effect transistor (NMOS), and the protection circuit 100′ is a diode, the positive electrode of which is connected to the gate terminal (gate) g′ of the NMOS. The negative electrode of the diode and the body terminal b′ of the NMOS both are shown as being grounded. In the process of manufacturing the NMOS, the protection circuit 100′ is connected to a conductive layer from which the gate terminal g′ is to be formed before the conductive layer from which the gate terminal g′ is to be formed is processed (e.g., etched) to form the gate terminal g′ by a plasma process. Thus, in the plasma process, when a certain voltage is induced on the gate terminal g′ due to plasma, the protection circuit 100′ can release the charges accumulated on the gate terminal g′, thereby reducing the voltage at the gate terminal g′.

In the following, a turn-on threshold refers to a minimum bias voltage for forward conduction of a unidirectional conduction circuit or a unidirectional conduction device, and a breakdown threshold refers to a minimum bias voltage for reverse breakdown of the unidirectional conduction circuit or the unidirectional conduction device. As shown in FIG. 1, when the positive bias voltage at the gate terminal g′ is greater than or equal to the turn-on threshold Vt′ (e.g., Vt′=0.6 Volts (V)) of the unidirectional conduction device (diode), the diode is in a forward conduction state, so that the charges accumulated on the gate terminal g′ can be released to ground through the diode 100′. When the absolute value of the reverse bias voltage at the gate terminal g′ is greater than or equal to the breakdown threshold Vb′ (e.g., Vb′=5 V) of the diode, the diode is in a reverse conduction (breakdown) state and the charges accumulated on the gate terminal g′ can also be released to ground through the diode 100′. Thus, the device 200 can be protected.

When the bias voltage on the gate terminal g′ is between the above-described two states (e.g., greater than −Vb′ (−5 V) and less than Vt′ (+0.6 V)), the diode is in an off state, at this point the charges accumulated on the gate terminal g′ are released through a leakage current of the diode. Considering that the leakage current of the diode is much smaller than the currents in the forward conduction and reverse conduction states thereof, so in this case, the release rate of the charges accumulated on the gate terminal g′ can be very slow, and in the case of employing the protection circuit 100′ shown in FIG. 1, it is still possible to introduce plasma damage in the gate capacitance of the NMOS.

In addition, it is often necessary to further measure the electrical characteristics of the device (such as NMOS) therein during or after the manufacture of the semiconductor apparatus. Charges may also be accumulated at the terminal due to the application of a bias voltage (test voltage) to the terminal. Taking a test of a Capacitance Voltage (CV) characteristic as an example, during the test, a test input signal can be applied to a terminal of the NMOS through a signal generation circuit (not shown in the figure). Taking the diode described above as an example, in FIG. 1, when it is necessary to test the CV characteristic of the gate capacitance of the NMOS between −Vdd1 and 0 (wherein 0<Vdd1<Vb′, e.g., setting Vdd1=1.2V), if the negative (reverse) bias voltage Vg′ on the gate terminal g′ is within a normal target test voltage range of −Vdd1 and 0, the diode is in an off state, and the test of the NMOS may not be affected. When the absolute value of the negative bias voltage Vg′ on the gate terminal g′ is greater than or equal to the breakdown threshold Vb′ of the diode, the diode is reversely broken down, causing the gate terminal g′ to conduct with ground, thus preventing a more serious negative bias voltage from being accumulated on the gate terminal g′, and to play a role in protecting the semiconductor apparatus during the test.

However, during the test, if it is necessary to test the CV characteristic of the gate capacitance of the NMOS between 0 and +Vdd2 (wherein Vdd2>0), when the positive bias voltage Vg′ on the gate terminal g′ is greater than the turn-on threshold Vt′ of the diode, the diode in FIG. 1 is turned on in the forward direction, causing that the test cannot be performed normally. In general, the turn-on threshold Vt′ of the diode is very small, and it is difficult to satisfy the measurement of the electrical characteristics of the NMOS in the case of Vdd2>Vt′.

In a similar way, FIG. 2 shows a structural schematic diagram of another semiconductor apparatus, which is different from the semiconductor apparatus shown in FIG. 1 only in that: in which a connection direction of the diode of the protection circuit 100′ in the semiconductor apparatus is opposite to that in FIG. 1. Similarly, the diode can also play a certain role in protection during the manufacturing process of the NMOS. However, in the case of which the voltage difference between an end (ground) of the diode remoting from the gate and the gate g′ is greater than the threshold of the diode, the diode is turned on, causing that the test cannot be performed normally.

Similarly, when the bias voltage on the gate terminal g′ is between the turn-on threshold Vt′ (e.g., 0.6V, which may also be given a negative value of −0.6V compared to the circuit configuration of FIG. 1, considering that its connection direction is opposite to that shown in FIG. 1) and the breakdown threshold Vb′ (e.g., +5 V) of the diode, the release rate of the charges accumulated on the gate terminal g′ is relatively slow, and there may still be a risk of introducing plasma damage in the gate capacitance.

In addition, during the test of the semiconductor apparatus, when the protection circuit 100′ shown in FIG. 2 is adopted, although a certain protection can be provided in the target test voltage range of 0 to +Vdd2, it is difficult to realize a normal test in the target test voltage range of −Vdd1 to −Vt′ because the turn-on threshold of the diode is generally small.

In order to avoid excessive absolute values of the bias voltage at the terminal of the device during the manufacturing process of the semiconductor apparatus and to provide test protection for the semiconductor apparatus in a larger target test voltage range, embodiments of the present disclosure are proposed.

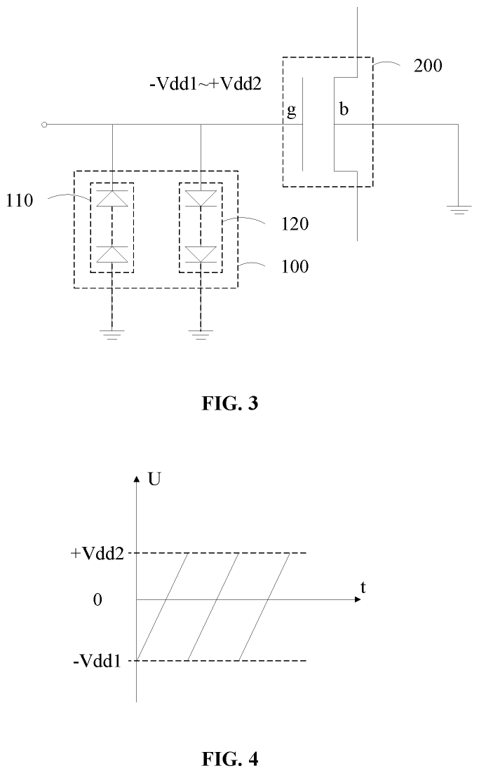

In an exemplary embodiment of the present disclosure, a semiconductor apparatus is presented. As shown in FIG. 3, the semiconductor apparatus includes: a device 200 having a terminal; and a protection circuit 100 configured to be connected to the terminal of the device 200. The protection circuit 100 can include at least two unidirectional conduction circuits (illustrated in FIG. 3 as a first unidirectional conduction circuit 110 and a second unidirectional conduction circuit 120) connected in anti-parallel. The two unidirectional conduction circuits are configured to have current directions opposite to each other in an on state. The protection circuit 100 can be so configured that, when the voltage at the terminal of the device 200 is out of a predetermined protection voltage range, at least one of the two unidirectional conduction circuits is turned on to release the charges accumulated at the terminal.

In some embodiments, the device 200 can be embodied as a variable capacitor, wherein the terminal includes an electrode terminal of the variable capacitor. Between the electrode terminals, the capacitance of the variable capacitor is adjustable.

Alternatively, in some embodiments, the device 200 can also be a field effect transistor, wherein the terminal includes a gate terminal of the field effect transistor. For example, the field effect transistor can be included in a test unit. In some embodiments, the test unit can be provided for monitoring the manufacturing process during a wafer process.

During the manufacturing process of the semiconductor apparatus, the protection circuit 100 is connected to the conductive layer from which a terminal of the device 200 is formed prior to a plasma process (e.g., plasma etching). In FIG. 3, the operation principle of the protection circuit 100 is described in detail by taking the device 200 is an NMOS as an example.

Specifically, the protection circuit 100 can include a first unidirectional conduction circuit 110 and a second unidirectional conduction circuit 120. Each unidirectional conduction circuit can include at least one unidirectional conduction device. As shown in FIG. 3, specifically the unidirectional conduction device can be a diode or the like.

For convenience of illustration, it is assumed that the bias voltage on the gate terminal g of the NMOS generated due to the plasma process is Vg, a first turn-on threshold of the first unidirectional conduction circuit 110 is Vt1, a first breakdown threshold of the first unidirectional conduction circuit 110 is Vb1, a second turn-on threshold of the second unidirectional conduction circuit 120 is Vt2, a second breakdown threshold of the second unidirectional conduction circuit 120 is Vb2, and Vb1>Vt1>0, Vb2>Vt2>0. For simplicity, it is further assumed that Vt1<Vb2, Vt2<Vb1. In other cases, a person skilled in the art can appropriately adjust the protection circuit 100 according to the exemplary embodiment of the present disclosure without creative work, to realize a protection of the semiconductor apparatus, which is not described in detail herein.

When the gate terminal g is reversely biased (i.e., the bias voltage Vg thereon is a negative value), if Vg≤−Vt1, that is, |Vg|≥Vt1, the first unidirectional conduction circuit 110 is in a forward conduction state. In this case, the charges accumulated on the gate terminal g can be rapidly released by the forward conduction current of the first unidirectional conduction circuit 110.

When the gate terminal g is forward biased (i.e., the bias voltage Vg thereon is a positive value), if Vg≥Vt2, the second unidirectional conduction circuit 120 is in a forward conduction state. In this case, the charges accumulated on the gate terminal g can be rapidly released by the forward conduction current of the second unidirectional conduction circuit 120.

When the bias voltage Vg on the gate terminal g satisfies −Vt1<Vg<Vt2, both the first unidirectional conduction circuit 110 and the second unidirectional conduction circuit 120 are in the off state.

In this way, breakdown due to the charges accumulated on the gate terminal g can be avoided. Furthermore, since Vt1, Vt2 can be set to be smaller than the breakdown thresholds Vb1, Vb2, the maximum value of the bias voltage Vg that may be accumulated on the gate terminal g is greatly reduced (e.g., the absolute value |Vg| thereof is smaller than the maximum value of Vt1 and Vt2) as compared to the solution shown in FIG. 1 or FIG. 2. Thus, a protection circuit 100 having a better protection effect is proposed.

The protection circuit 100 in FIG. 3 can also be used in testing electrical characteristics of the NMOS. In some embodiments, the terminal of the device 200 can be used to receive a test voltage. The test voltage can be within a target test voltage range. By setting the appropriate first turn-on thresholds Vt1 and second turn-on thresholds Vt2, the bias voltage Vg on the gate terminal g can cover the target test voltage range (e.g., −Vdd1 to +Vdd2, Vdd1 and Vdd2 may be equal or unequal) without exceeding a predetermined safe voltage threshold Vs. For example, in some embodiments, the safe voltage threshold may be set at or close to the breakdown voltage of the gate capacitance of the transistor. In general, Vs can be set as a voltage value greater than or much greater than a voltage value in the target test voltage range, for example, Vs can be set to be greater than Vdd1 and Vdd2. According to the embodiment of the present disclosure, the voltage bias protection in different directions during the test can be realized.

In a specific example, the turn-on threshold of each of the unidirectional conduction circuits is set to be greater than the corresponding test voltage. For example, the turn-on threshold of each of the unidirectional conduction circuits can be set to be greater than the maximum value of the absolute value of the test voltage. When the voltage Vg applied to the gate terminal g of the NMOS is within the test voltage range of −Vdd1 to +Vdd2, the first unidirectional conduction circuit 110 and the second unidirectional conduction circuit 120 are both in the off state, and the characteristic parameter test of the NMOS may not be affected.

Certainly, in other specific examples, the first turn-on threshold Vt1 of the first unidirectional conduction circuit 110 and the second turn-on threshold Vt2 of the second unidirectional conduction circuit 120 can also be set respectively based on the maximum values of the test voltages in different bias directions.

In addition, the first turn-on threshold Vt1 and the second turn-on threshold Vt2 can either be equal or unequal, to meet the requirements of different semiconductor apparatuses.

In some embodiments, the protection voltage range can be set to contain or be equal to the target test voltage range. In this way, the protection circuit 100 satisfying the protection voltage range can prevent or reduce plasma damage to the device during the manufacturing process of the semiconductor apparatus. On the other hand, since the target test voltage range is within the protection voltage range, the protection circuit 100 can still provide protection for the device during the test. In addition, the protection voltage range can be set to contain or be equal to the target test voltage range, and can also make the protection circuit 100 not be turned on too early during the test to affect the normal performance of the test.

In some embodiments, the safe voltage threshold Vs is the safe voltage threshold Vs (Vs>0) associated with the terminal of the device 200. As an example, in some embodiments, the safe voltage threshold can be a breakdown voltage of a capacitance associated with the terminal, such as a breakdown voltage of a gate dielectric (or a gate capacitance) of a transistor. It should be understood that the present application is not limited to that. The turn-on threshold Vt of each of the unidirectional conduction circuits can be set to be less than or equal to the safe voltage threshold Vs, to ensure that the semiconductor apparatus is safe during the test. Taking the aforementioned NMOS as an example, when the reverse bias voltage Vg on the gate terminal g of the NMOS (which is a negative value) is less than −Vs, that is, the absolute value |Vg| of the negative bias voltage on the gate terminal g of the NMOS is greater than Vs, the first unidirectional conduction circuit 110 is in the conduction state, thereby clamping the absolute value of the voltage Vg of the gate terminal g of the NMOS below the safe voltage threshold value Vs. In a Similar way, when the (forward) bias voltage Vg of the gate terminal g of the NMOS is greater than Vs, the second unidirectional conduction circuit 120 is in the conduction state, thereby clamping the absolute value of the voltage Vg of the gate terminal g of the NMOS below the safe voltage threshold Vs. In this way, the NMOS transistor can be prevented from being broken down.

In General, the maximum value of the absolute value of the protection voltage range is set to be less than or equal to the safe voltage threshold, thereby achieving a comprehensive protection during the manufacture and test of the semiconductor apparatus. In particular, in the manufacturing process of the semiconductor apparatus, a protection voltage range below the safe voltage threshold can be realized by the protection circuit 100, so that the reliability of the manufacturing process is further ensured, and the yield of the semiconductor apparatus is improved.

During the test, a signal generation circuit (not shown in the figure), a characteristic acquisition circuit (not shown in the figure), and the like can be set up, wherein the signal generation circuit is configured to provide a test input signal to a terminal of the device 200. In an exemplary embodiment, the test input signal is a scan voltage signal as shown in FIG. 4, and the test voltage Vtest satisfies −Vdd1≤Vtest≤+Vdd2.

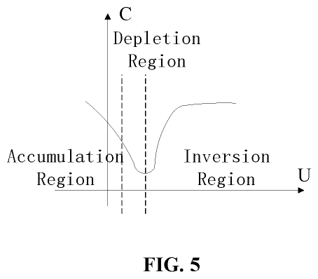

The characteristic acquisition circuit is configured to acquire the characteristic parameter of the device 200, to determine the electrical performance of the device 200. In an exemplary embodiment, a CV characteristic of a gate capacitance of an NMOS in the semiconductor apparatus can be tested. For the NMOS, the CV characteristic curve of its gate capacitance is shown in FIG. 5, having an accumulation region, a depletion region, and an inversion region.

Further, one unidirectional conduction circuit can include at least one unidirectional conduction device. As shown in FIG. 3, specifically the unidirectional conduction device can be a diode or the like. Since each unidirectional conduction device has a certain turn-on threshold, the turn-on threshold of each unidirectional conduction circuit can be controlled by selecting the turn-on threshold of each unidirectional conduction device and the number of the unidirectional conduction devices connected in series in the same direction.

In one specific example, one unidirectional conduction circuit can include at least two unidirectional conduction devices connected in series in the same direction, and respective turn-on thresholds of the unidirectional conduction devices in the same unidirectional conduction circuit are the same, to simplify the setting of the unidirectional conduction circuit. It should be noted that the same turn-on threshold does not exclude a slight deviation between the turn-on thresholds due to the factors such as the manufacturing process of the device and the like, in other words, the unidirectional conduction devices having substantially the same turn-on thresholds can also be used to form the unidirectional conduction circuit.

In another specific example, one unidirectional conduction circuit can include at least two unidirectional conduction devices connected in series in the same direction and having different turn-on thresholds, to improve the flexibility in setting the unidirectional conduction circuit. In the unidirectional conduction circuit, the unidirectional conduction device with a greater absolute value of the turn-on threshold facilitates the reduction of the total number of the unidirectional conduction devices in the unidirectional conduction circuit, thereby simplifying the circuit structure, and the unidirectional conduction device with a smaller absolute value of the turn-on threshold value can facilitate a fine adjustment of the turn-on threshold of the unidirectional conduction circuit to meet the requirements of finer protection and/or test.

In one specific example, the first unidirectional conduction circuit 110 and the second unidirectional conduction circuit 120 can be formed by connecting, in series, three diodes with the turn-on threshold of 0.6V and the breakdown threshold of 5V, respectively, in a connection way shown in FIG. 3, and the first unidirectional conduction circuit 110 and the second unidirectional conduction circuit 120 are connected in opposite directions in the semiconductor apparatus. Then, the first turn-on threshold of the first unidirectional conduction circuit 110 is −1.8V, and the first breakdown threshold of the first unidirectional conduction circuit 110 is +15V. The second turn-on threshold of the second unidirectional conduction circuit 120 is +1.8V, and the second breakdown threshold of the second unidirectional conduction circuit 120 is −15V. As shown in FIG. 3, during the manufacturing process, charges are possible to be accumulated at the terminal due to the formation of the terminal by the plasma process, thereby causing a bias voltage. When the bias voltage Vg on the gate terminal g satisfies Vg<−1.8V or Vg>+1.8V, the first unidirectional conduction circuit 110 or the second unidirectional conduction circuit 120 is in an on state, respectively, thereby rapidly releasing the accumulated charges on the gate terminal g, to protect the gate capacitance of the NMOS.

While in the test process, it is assumed that the target test voltage range of the CV test is −1.2V to +1.2V, that is, when the bias voltage Vg on the gate terminal g satisfies −1.2V≤Vg≤1.2V, both the first unidirectional conduction circuit 110 and the second unidirectional conduction circuit 120 are in the off state within the range, and normal measurement may not be affected.

On the other hand, due to the above-described settings of the first unidirectional conduction circuit 110 and the second unidirectional conduction circuit 120, the bias voltage Vg on the gate terminal g of the NMOS will not exceed the range of −1.8V to +1.8V during the test. Thus, the device can be protected from being broken down. In other specific examples, the number of the unidirectional conduction devices connected in series in the first unidirectional conduction circuit 110 and the second unidirectional conduction circuit 120 can be determined according to a required protection voltage range.

The terms “front,” “back,” “top,” “bottom,” “over,” “under” and the like, as used herein, if any, are used for descriptive purposes and not necessarily for describing permanent relative positions. It should be understood that such terms are interchangeable under appropriate circumstances such that the embodiments of the disclosure described herein are, for example, capable of operation in other orientations than those illustrated or otherwise described herein.

The term “exemplary”, as used herein, means “serving as an example, instance, or illustration”, rather than as a “model” that would be exactly duplicated. Any implementation described herein as exemplary is not necessarily to be construed as preferred or advantageous over other implementations. Furthermore, there is no intention to be bound by any expressed or implied theory presented in the preceding technical field, background, summary or detailed description.

The term “substantially”, as used herein, is intended to encompass any slight variations due to design or manufacturing imperfections, device or component tolerances, environmental effects and/or other factors. The term “substantially” also allows for variation from a perfect or ideal case due to parasitic effects, noise, and other practical considerations that may be present in an actual implementation.

In addition, the foregoing description may refer to elements or nodes or features being “connected” or “coupled” together. As used herein, unless expressly stated otherwise, “connected” means that one element/node/feature is electrically, mechanically, logically or otherwise directly joined to (or directly communicates with) another element/node/feature. Likewise, unless expressly stated otherwise, “coupled” means that one element/node/feature may be mechanically, electrically, logically or otherwise joined to another element/node/feature in either a direct or indirect manner to permit interaction even though the two features may not be directly connected. That is, “coupled” is intended to encompass both direct and indirect joining of elements or other features, including connection with one or more intervening elements.

In addition, certain terminology, such as the terms “first”, “second” and the like, may also be used in the following description for the purpose of reference only, and thus are not intended to be limiting. For example, the terms “first”, “second” and other such numerical terms referring to structures or elements do not imply a sequence or order unless clearly indicated by the context.

Further, it should be noted that, the terms “comprise”, “include”, “have” and any other variants, as used herein, specify the presence of stated features, integers, steps, operations, elements, and/or components, but do not preclude the presence or addition of one or more other features, integers, steps, operations, elements, components, and/or groups thereof.

In this disclosure, the term “provide” is intended in a broad sense to encompass all ways of obtaining an object, thus the expression “providing an object” includes but is not limited to “purchasing”, “preparing/manufacturing”, “disposing/arranging”, “installing/assembling”, and/or “ordering” the object, or the like.

Furthermore, those skilled in the art will recognize that boundaries between the above described operations are merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments. However, other modifications, variations and alternatives are also possible. The description and drawings are, accordingly, to be regarded in an illustrative rather than in a restrictive sense.

Although some specific embodiments of the present disclosure have been described in detail with examples, it should be understood by a person skilled in the art that the above examples are only intended to be illustrative but not to limit the scope of the present disclosure. The embodiments disclosed herein can be combined arbitrarily with each other, without departing from the scope and spirit of the present disclosure. It should be understood by a person skilled in the art that the above embodiments can be modified without departing from the scope and spirit of the present disclosure. The scope of the present disclosure is defined by the attached claims.

What is claimed is:

1. A semiconductor apparatus, comprising:
a device having a terminal; and
a protection circuit configured to be connected to the terminal of the device, the protection circuit comprising at least two unidirectional conduction circuits connected in anti-parallel, the two unidirectional conduction circuits configured to have current directions opposite to each other in an on state,
wherein the protection circuit is so configured that, at least one of the two unidirectional conduction circuits is turned on to release charges accumulated at the terminal when a voltage at the terminal of the device is out of a predetermined protection voltage range.

2. The semiconductor apparatus according to claim 1, wherein,
the terminal of the device is used to receive a test voltage within a target test voltage range;
a turn-on threshold of each of the unidirectional conduction circuits is set to be greater than a maximum value of an absolute value of the test voltage.

3. The semiconductor apparatus according to claim 2, wherein, the protection voltage range is set to contain or be equal to the target test voltage range.

4. The semiconductor apparatus according to claim 2, wherein,
the device has a safe voltage threshold associated with the terminal;
the turn-on threshold of each of the unidirectional conduction circuits is set to be less than or equal to the safe voltage threshold.

5. The semiconductor apparatus according to claim 4, wherein, the maximum value of the absolute value of the protection voltage range is set to be less than or equal to the safe voltage threshold.

6. The semiconductor apparatus according to claim 1, wherein, each of the unidirectional conduction circuits comprises at least one unidirectional conduction device.

7. The semiconductor apparatus according to claim 1, wherein, each of the unidirectional conduction circuits comprises at least two unidirectional conduction devices connected in series in a same direction.

8. The semiconductor apparatus according to claim 7, wherein, the at least two unidirectional conduction devices connected in series in the same direction have a same turn-on threshold.

9. The semiconductor apparatus according to claim 7, wherein, the at least two unidirectional conduction devices connected in series in the same direction have different turn-on thresholds.

10. The semiconductor apparatus according to claim 6, wherein, the unidirectional conduction device is a diode.

11. The semiconductor apparatus according to claim 7, wherein, the unidirectional conduction device is a diode.

12. The semiconductor apparatus according to claim 8, wherein, the unidirectional conduction device is a diode.

13. The semiconductor apparatus according to claim 9, wherein, the unidirectional conduction device is a diode.

14. The semiconductor apparatus according to claim 1, wherein,
the device is a variable capacitor, wherein the terminal comprises an electrode terminal of the variable capacitor; or
the device is a field effect transistor, wherein the terminal comprises a gate terminal of the field effect transistor.

15. The semiconductor apparatus according to claim 1, wherein, the charges accumulated at the terminal are charges accumulated when the terminal is formed by a plasma process.

16. The semiconductor apparatus according to claim 1, wherein, the charges accumulated at the terminal are charges accumulated when a test voltage is applied to the terminal.
